(19) United States
(12) Patent Application Publication
(10) Pub. No.: US 2025/0364278 A1
(43) Pub. Date: Nov. 27, 2025

(54) LASER PROCESSING DEVICE AND WAFER DICING METHOD INCLUDING THE SAME

(71) Applicant: SAMSUNG ELECTRONICS CO., LTD., Suwon-si (KR)

(72) Inventor: Kwangyong LEE, Suwon-si (KR)

(21) Appl. No.: 19/201,383

(22) Filed: May 7, 2025

(30) Foreign Application Priority Data
May 24, 2024 (KR) 10-2024-0068023

(51) Int. Cl. H01L 21/67; G02B 27/10; H01L 21/268; H01L 21/78

(52) U.S. Cl. CPC H01L 21/67092; G02B 27/1093; H01L 21/268; H01L 21/78

(57) ABSTRACT

A laser processing device includes a beam generator configured to generate a laser beam, and a beam shaper configured to split the laser beam generated from the beam generator into a plurality of laser beams through diffraction and form a pattern of the laser beam based on a beam matrix, wherein the beam matrix includes beam patterns having a plurality of beam sizes.

### CROSS-REFERENCE TO RELATED APPLICATION

This application is based on and claims priority under 35 U.S.C. § 119 to Korean Patent Application No. 10-2024-0068023, filed on May 24, 2024, in the Korean Intellectual Property Office, the disclosure of which is incorporated by reference herein in its entirety.

### BACKGROUND

The inventive concept relates to a laser processing device and a wafer dicing method including the same.

The laser processing process refers to a process of processing the shape or physical properties of a surface of a workpiece by scanning a laser beam on the surface of the workpiece. The laser processing process includes, for example, a patterning process that forms a pattern on the surface of the workpiece, a process that modifies the physical properties of the workpiece, such as wafer annealing, a forming process that changes the shape of the workpiece through heat melting, and a cutting process that cuts the workpiece into multiple units through heat melting.

The wafer dicing process using a conventional laser beam cuts the workpiece by irradiating the workpiece with laser light in a wavelength band with a high absorption rate to heat and melt the workpiece. In other words, a metal or insulating layer included in the workpiece may be removed by using the thermal energy of the laser beam. When forming a groove in the workpiece using the laser beam, the shape of the groove may be formed in various ways depending on the laser beam matrix.

### SUMMARY OF THE INVENTION

The inventive concept provides a laser processing device for effective cutting and a wafer dicing method including the same.

In addition, the inventive concept is not limited to the mentioned above, and other inventive concepts not mentioned are clearly understood by those skilled in the art from the description below.

According to an aspect of the inventive concept, there is provided a laser processing device including a beam generator configured to generate a laser beam, and a beam shaper configured to split the laser beam generated by the beam generator into a plurality of laser beams through diffraction and to form at least one beam pattern of the plurality of laser beams via a beam matrix, wherein the at least one beam pattern comprises a plurality of beam sizes.

According to another aspect of the inventive concept, there is provided a wafer dicing method including preparing a wafer having a plurality of device formation areas where a plurality of semiconductor devices are located and a scribe lane area defining the plurality of device formation areas, and forming a groove that at least partially penetrates the wafer in the scribe lane area, wherein the forming of the groove includes irradiating a first laser beam onto an upper surface of the wafer, wherein the first laser beam is split into at least one pattern of a plurality of laser beams via a beam matrix, wherein the at least one pattern has a plurality of beam sizes.

According to another aspect of the inventive concept, there is provided a wafer dicing method including preparing a wafer having a plurality of device formation areas where a plurality of semiconductor devices are located and a scribe lane area defining the plurality of device formation areas, generating a laser beam, splitting the laser beam into a plurality of laser beams arranged in at least one pattern via a beam matrix, and irradiating the wafer with the plurality of laser beams arranged in the at least one pattern, wherein the at least one pattern comprises first beam patterns and second beam patterns having a diameter at least twice a diameter of the first beam patterns, and wherein a distance between adjacent ones of the second beam patterns is less than a diameter of each of the second beam patterns.

### BRIEF DESCRIPTION OF THE DRAWINGS

Embodiments will be more clearly understood from the following detailed description taken in conjunction with the accompanying drawings in which:

FIG. 1A is a side view of a laser processing device according to an embodiment;

FIG. 1B is a side view of a laser processing device according to an embodiment;

FIG. 2A is a plan view of a beam matrix included in a laser processing device according to an embodiment;

FIG. 2B is a diagram of Gaussian distribution of a laser beam based on the beam matrix of FIG. 2A;

FIG. 3A is a diagram of a beam matrix included in a laser processing device according to an embodiment;

FIG. 3B is a diagram of Gaussian distribution of a laser beam based on the beam matrix of FIG. 3A;

FIG. 4A is a diagram of a beam matrix included in a laser processing device according to an embodiment;

FIG. 4B is a diagram of Gaussian distribution of a laser beam based on the beam matrix of FIG. 4A;

FIG. 5 is a plan view of a beam matrix included in a laser processing device according to an embodiment;

FIG. 6 is a plan view of a beam matrix included in a laser processing device according to an embodiment;

FIG. 7 is a schematic flowchart of a wafer dicing method according to an embodiment;

FIGS. 8A, 9A, 10A, 11A, and 12A are perspective views of a wafer to illustrate a wafer dicing method in order of process sequence, according to an embodiment;

FIGS. 8B, 9B, 9C, 10B, 11B, and 12B are cross-sectional views of a wafer to illustrate a wafer dicing method in order of process sequence, according to an embodiment; and

FIG. 13 is a schematic flowchart of a wafer dicing method according to an embodiment.

### DETAILED DESCRIPTION

Since the embodiments are subject to various changes and have various forms, some embodiments may be illustrated in the drawings and described in detail. However, this is not intended to limit the embodiments to the specific disclosure form.

Hereinafter, the embodiments are described in detail with reference to the attached drawings. The same reference numerals are used for the same components in the drawings and duplicate descriptions thereof are omitted.

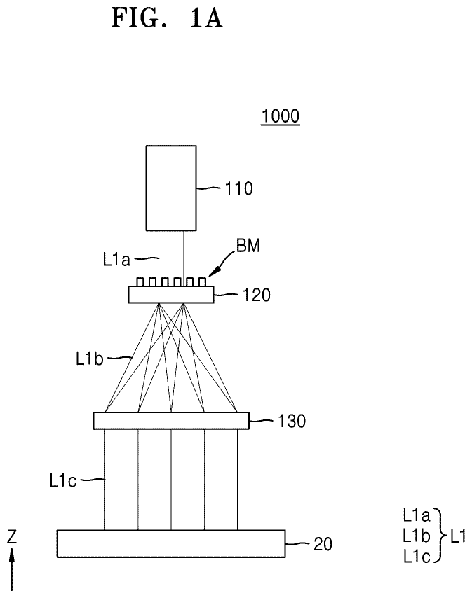

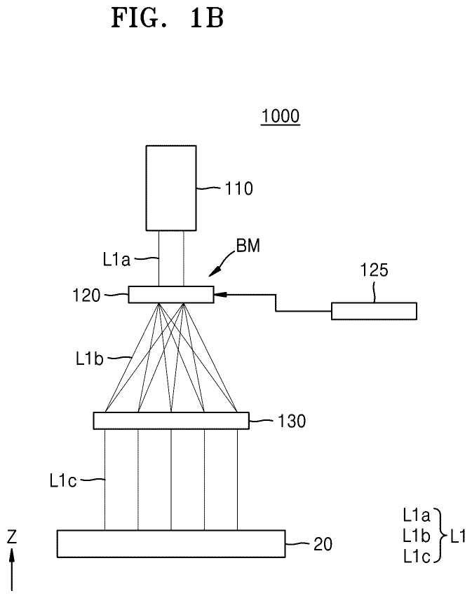

FIGS. 1A and 1B are side views of a laser processing device 1000 according to an embodiment.

Referring to FIGS. 1A and 1B, the laser processing device 1000 according to an embodiment may include a beam generator 110, a beam shaper 120, and a condensing optical system 130. The laser processing device 1000 may process a wafer 20 using a laser beam L1.

The beam generator 110 may generate a laser beam L1a for processing the wafer 20. The beam generator 110 of the laser processing device 1000 may be provided as a single laser light source or may be provided as a plurality of laser light sources.

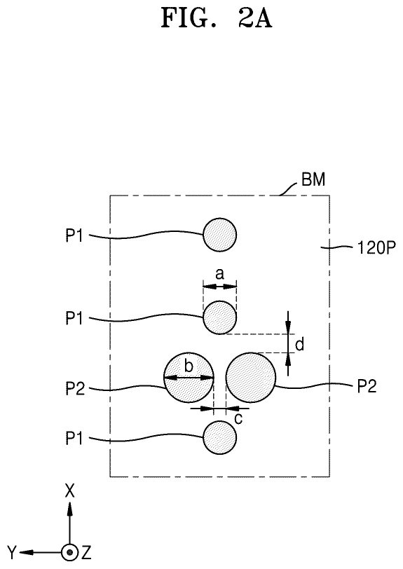

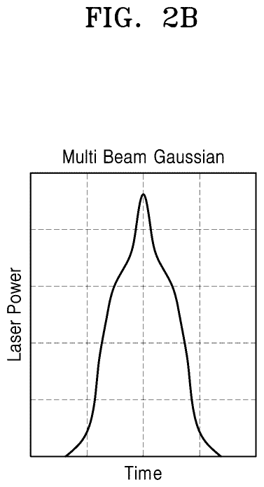

The beam shaper 120 may split the laser beam L1a from the beam generator 110 into a plurality of laser beams L1b through diffraction. The beam shaper 120 may form a pattern of the laser beam L1 based on a beam matrix BM. The beam matrix BM may include a beam pattern (e.g., P1 in FIG. 2A) that defines the size of beams and the distance between beams. The beam matrix BM may be understood as a certain concavo-convex pattern formed on the beam shaper 120 or a setting value (or data) input to the beam shaper 120 so that the beam shaper 120 forms a certain pattern of laser beams. A detailed description of the beam matrix BM is described below with reference to FIG. 2A.

In some embodiments, the beam shaper 120 may include a diffractive optical element (DOE). The beam shaper 120 may include a fixed DOE or a controlled DOE.

The fixed DOE may include a DOE that implements a fixed beam pattern. The fixed DOE may have a structure in which a concavo-convex pattern is formed on a light-transmitting plate. The beam shaper 120 in FIG. 1A, which is a fixed DOE, is shown to include a concavo-convex pattern based on the beam matrix BM. The beam shaper 120 in FIG. 1A may form a pattern of the laser beam L1 through the concavo-convex pattern based on the beam matrix BM.

The controlled DOE refers to an element capable of controlling at least one of the size of the split beam, a distance between beams, and a beam pattern. The controlled DOE may be controlled by being connected to a controller (e.g., personal computer (PC)). The beam shaper 120 in FIG. 1B, which is a controlled DOE, is shown to be connected to a controller 125. The beam shaper 120 in FIG. 1B may receive information about the beam matrix BM from the controller 125 and form the pattern of the laser beam L1 based on the beam matrix BM.

The condensing optical system 130 may be placed between the beam shaper 120 and the wafer 20. The plurality of laser beams L1b split by the beam shaper 120 may be processed by the condensing optical system 130. The condensing optical system 130 may condense laser beams L1c on certain positions on the wafer 20. The condensing optical system 130 may include at least one lens.

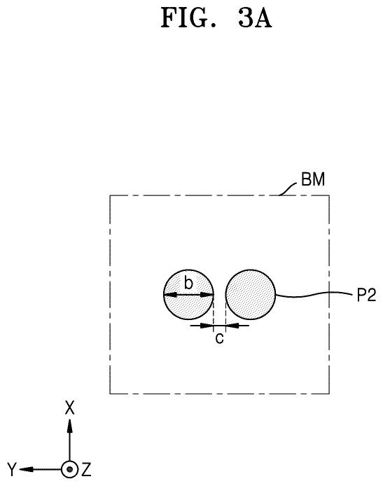

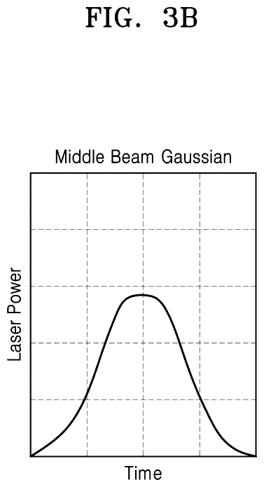

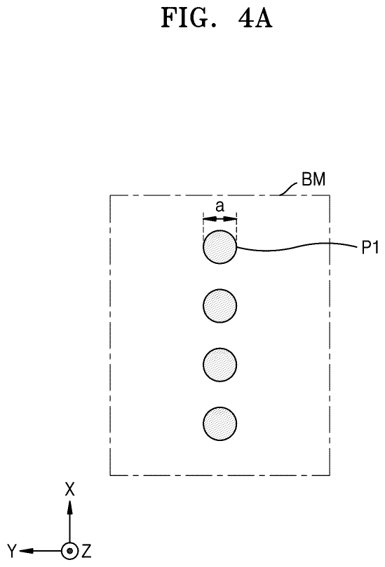

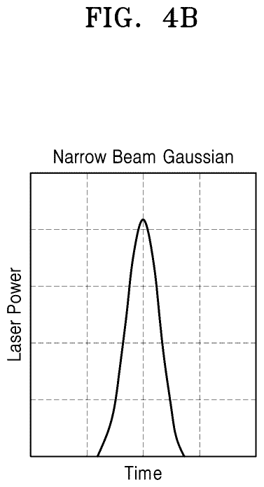

FIG. 2A is a plan view of a beam matrix included in a laser processing device according to an embodiment and FIG. 2B is a diagram of Gaussian distribution of a laser beam based on the beam matrix of FIG. 2A. FIG. 3A is a diagram of a beam matrix included in a laser processing device according to an embodiment and FIG. 3B is a diagram of Gaussian distribution of a laser beam based on the beam matrix of FIG. 3A. FIG. 4A is a diagram of a beam matrix included in a laser processing device according to an embodiment and FIG. 4B is a diagram of Gaussian distribution of a laser beam based on the beam matrix of FIG. 4A.

In an embodiment, the beam matrix BM may include a concavo-convex pattern formed on the beam shaper 120 (see FIG. 1A) or a design for the concavo-convex pattern. In an embodiment, the beam matrix BM may include pattern design data input from the controller (125 in FIG. 1B) to the beam shaper (120 in FIG. 1B) or a pattern formed on the beam shaper 120 (see FIG. 1B) by the design data.

Referring to FIG. 2A, the beam matrix BM includes beam patterns having a plurality of beam sizes. Since the beam matrix BM includes the beam patterns having a plurality of beam sizes, the beam matrix BM may be understood as a multi-beam matrix. The beam patterns having the plurality of beam sizes may include first beam patterns P1 having a first beam size a and second beam patterns P2 having a second beam size b. The beam size may refer to a diameter of the beam.

The first beam size a is different from the second beam size b. In an embodiment, the second beam size b may be twice or more of the first beam size a (2a≤b) or twice or more and ten times or less of the first beam size a (2a≤b≤10a).

In an embodiment, the first beam patterns P1 may be arranged in a first horizontal direction (e.g., X direction). In an embodiment, the second beam patterns P2 may be arranged in a second horizontal direction (e.g., Y direction) perpendicular to the first horizontal direction (e.g., X direction).

In an embodiment, a distance c between adjacent second beam patterns P2 may be less than the second beam size b of the second beam patterns P2 (c<b). In an embodiment of FIG. 2A, since the second beam patterns P2 are arranged in the second horizontal direction (e.g., Y direction), the distance c between the adjacent second beam patterns P2 may include a distance in the second horizontal direction (e.g., Y direction).

In an embodiment, a distance d between the first beam pattern P1 and the second beam pattern P2 adjacent to each other may be greater than the first beam size a of the first beam patterns P1. In an embodiment, the first beam pattern P1 and the second beam pattern P2 may be adjacent to each other in the first horizontal direction (e.g., X direction). In this case, the distance d between the first beam pattern P1 and the second beam pattern P2 adjacent to each other may include a distance in the first horizontal direction (e.g., X direction).

In an embodiment, within the beam matrix BM, the first beam pattern P1 may be located at one end of the beam matrix BM in the first horizontal direction (e.g., X direction).

FIG. 2B shows a Gaussian distribution of a laser beam (e.g., multi-beam) based on the beam matrix BM of FIG. 2A, FIG. 3B shows a Gaussian distribution of a laser beam (e.g., middle beam) based on the beam matrix BM of FIG. 3A, and FIG. 4B shows a Gaussian distribution of a laser beam (e.g., narrow beam) based on the beam matrix BM of FIG. 4A.

The Gaussian distribution of each laser beam may correspond to the shape of a groove formed in the workpiece (e.g., the wafer 20 in FIGS. 1A and 1B) by each laser beam. For example, the shapes of the Gaussian distribution graphs shown in FIGS. 2B, 3B and 4B may be substantially the same or similar to the upside down cross-sections of the grooves formed by the laser beams based on the beam matrices BM of FIGS. 2A, 3A, and 4A, respectively.

Comparing FIG. 2B with FIG. 3B, the groove formed based on the beam matrix BM of FIG. 2A may have a smaller width and a greater depth than the groove formed based on the beam matrix BM of FIG. 3A. In addition, comparing FIG. 2B with FIG. 4B, the groove formed based on the beam matrix BM of FIG. 2A may have an enlarged entrance area compared to the groove formed based on the beam matrix BM of FIG. 4A while having a deep depth like the groove formed based on the beam matrix BM of FIG. 4A. The entrance area refers to an area adjacent to an upper surface of the workpiece (e.g., an upper surface of the wafer 20 to be irradiated by laser) to be irradiated by a laser beam.

The shape of the groove formed based on the beam matrix BM illustrated in FIG. 2A may have an approximately V-shape. That is, the groove formed in the workpiece by the laser processing device 1000 according to an embodiment may have a V-shape. That is, the horizontal width of the groove may narrow in a vertical direction toward the bottom of the groove. In an embodiment, the rate of change in the horizontal width of the groove at the entrance area of the groove (e.g., an area adjacent to the upper surface of the workpiece) may be less than the rate of change in the horizontal width of the groove at the bottom area of the groove. In an embodiment, the bottom area of the groove may have a pointed shape. That is, the bottom area of the groove may be V-shaped. This difference in Gaussian distribution (or difference in groove shape) may result from a difference in the beam pattern included in the beam matrix BM. The beam fluence (i.e., the energy of the beam per unit area) is inversely proportional to the beam size. Thus, when the beam size is large, the beam fluence is low, resulting in a Gaussian distribution with a wide width and a shallow depth. When the beam size is small, the beam fluence is low, resulting in a Gaussian distribution with a narrow width and a deep depth.

FIG. 3A shows that the beam matrix BM includes beam patterns of a single size. FIG. 3A shows that the beam matrix BM includes only the second patterns P2 included in the beam matrix BM of FIG. 2A. When the beam matrix BM includes only the second patterns P2 of a relatively large size as shown in FIG. 3A, a Gaussian distribution with a wide width and a shallow depth may be formed, as described above. Therefore, when a groove is formed in the workpiece by using the laser beam based on the beam matrix BM of FIG. 3A, the groove may have a wide U-shape. In this way, when the laser beam is applied to a wafer dicing method, the productivity of the semiconductor process may decrease.

FIG. 4A shows that the beam matrix BM includes beam patterns of a single size. FIG. 4A shows that the beam matrix BM includes only the first patterns P1 included in the beam matrix BM of FIG. 2. As shown in FIG. 4A, when the beam matrix BM includes only the first patterns P1 of a relatively small size, a re-melting void may be formed inside the workpiece due to high beam fluence. The re-melting void refers to a void inside the workpiece that is formed during a high-speed volatilization and solidification process of materials included in the workpiece when irradiated with a laser beam.

The beam matrix BM of the laser processing device 1000 according to an embodiment may include beam patterns having a plurality of beam sizes. That is, as illustrated in FIG. 2A, the beam matrix BM may include the first beam patterns P1 and the second beam patterns P2, which have different sizes. As such, since the beam matrix BM has beam patterns having a plurality of beam sizes, the laser processing device 1000 may suppress the formation of the re-melting void in the workpiece to form a groove with a deep depth.

As described above with reference to FIG. 2A, the first beam patterns P1 may be arranged in the first horizontal (e.g., X) direction (i.e., the first beam patterns P1 are aligned along the X direction). In an embodiment, the first horizontal direction may be parallel to a scan direction of the laser beam. In an embodiment, the first horizontal direction may be parallel to an extension direction of the groove of the workpiece formed by the laser processing device 1000. As such, by arranging the first beam patterns P1 parallel to the extension direction of the groove, the groove with a deep depth may be formed.

As described above with reference to FIG. 2A, the first beam pattern P1 may be located at one end in the first horizontal direction, within the beam matrix BM. Accordingly, the small-sized first beam patterns P1 may be first applied to the workpiece to deepen the groove of the workpiece formed by the laser processing device 1000.

As described above with reference to FIG. 2A, the second beam patterns P2 may be arranged in the second horizontal (e.g., Y) direction (i.e., the second beam patterns P2 are aligned along the Y direction). In an embodiment, the second horizontal direction may be perpendicular to the extension direction of the groove of the workpiece formed by the laser processing device 1000. As such, the width of the entrance area of the groove may be adjusted by arranging the second beam patterns P2 perpendicular to the extension direction of the groove. The formation of the re-melting void may be prevented by maintaining the width of the entrance area of the groove above a certain value.

As described above with reference to FIG. 2A, the distance c between adjacent second beam patterns P2 may be less than the second beam size b. Accordingly, interference may occur between the adjacent second beam patterns P2. Interference between laser beam patterns is a phenomenon that occurs when two or more laser beams meet in space, and can mean either destructive interference or constructive interference, depending on the phase, amplitude, and wavelength of the beams.

As described above with reference to FIG. 2A, the distance d between the first beam pattern P1 and the second beam pattern P2 that are adjacent to each other may be greater than the first beam size a of the first beam patterns P1. Accordingly, interference may not occur between the first beam pattern P1 and the second beam patternsP2 that are adjacent to each other.

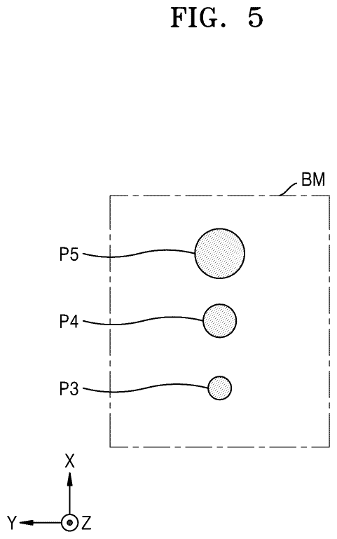

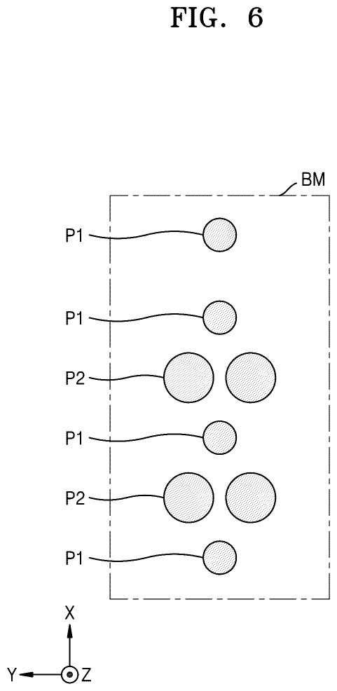

Each of FIGS. 5 and 6 is a plan view of a beam matrix included in a laser processing device according to an embodiment.

The beam matrix BM may include beam patterns of three or more sizes, as shown in FIG. 5. In an embodiment, the beam matrix BM may include a third beam pattern P3, a fourth beam pattern P4, and a fifth beam pattern P5, each having a different beam size. In an embodiment, the third beam pattern P3, the fourth beam pattern P4, and the fifth beam pattern P5 may be sequentially arranged in the first horizontal direction (e.g., X direction). Additionally, the beam matrix BM may include multiple beam patterns, as shown in FIG. 6. FIGS. 2A, 5, and 6 only illustrate the patterns of the beam matrix BM according to an embodiment and the patterns of the beam matrix BM are not limited thereto. The beam matrix BM is characterized in patterns having a plurality of beam sizes but the arrangement and number of patterns are not limited thereto and may be combined in various ways.

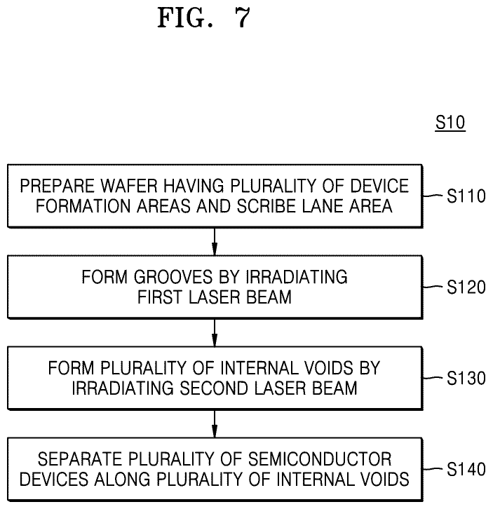

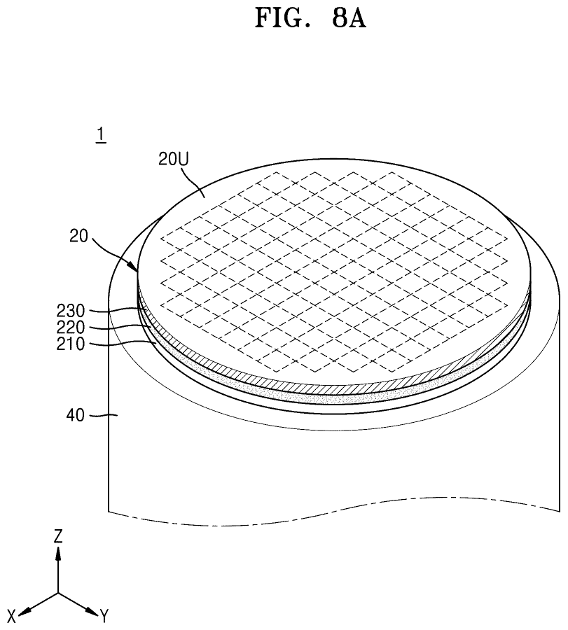

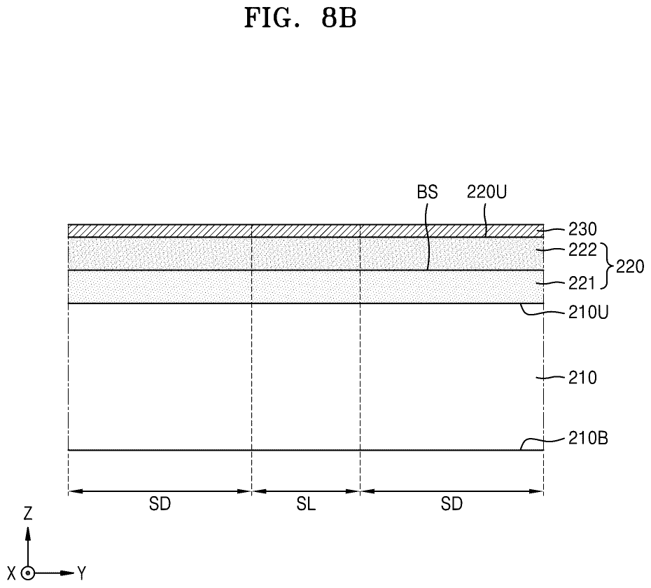

FIG. 7 is a schematic flowchart of a wafer dicing method according to an embodiment. FIGS. 8A, 9A, 10A, 11A, and 12A are perspective views of a wafer to illustrate a wafer dicing method in order of process sequence, according to an embodiment. FIGS. 8B, 9B, 9C, 10B, 11B, and 12B are cross-sectional views of a wafer to illustrate a wafer dicing method in order of process sequence, according to an embodiment.

Referring to FIG. 7, the wafer dicing method (S10) according to an embodiment may include preparing a wafer having a plurality of device formation areas and a scribe lane area (S110), forming grooves by irradiating a first laser beam (S120), forming a plurality of internal voids by irradiating a second laser beam (S130), and separating a plurality of semiconductor devices along the plurality of internal voids (S140).

The wafer dicing method (S10) may be described in detail with reference to FIGS. 8A to 12B below.

Referring to FIGS. 8A and 8B, the wafer 20 is mounted on a chuck table 40 with an upper surface 20U of the wafer 20 facing upward. In other words, the wafer 20 may be mounted on the chuck table 40 with the upper surface 230u of the protective layer 230 facing upward.

The wafer 20 may include a base substrate 210, an active layer 220, and a protective layer 230. In some embodiments, the active layer 220 may be formed on the base substrate 210 and the protective layer 230 may be formed on the active layer 220. In some embodiments, the active layer 220 may include an upper active layer 222 and a lower active layer 221 (FIG. 8B) which are combined with respect to a bonding surface BS.

The base substrate 210 of the wafer 20 may include silicon (Si). However, the material of the base substrate 210 is not limited to Si. For example, the base substrate 210 may include another semiconductor element, such as germanium (Ge) or a compound semiconductor, such as SiC, GaAs, InAs, or InP.

The base substrate 210 may have a silicon on insulator (SOI) structure. For example, the base substrate 210 may include a buried oxide (BOX) layer. The base substrate 210 of the wafer 20 may be referred to as an inactive layer.

The active layer 220 of the wafer 20 may be located on the upper surface 210U of the base substrate 210.

In some embodiments, the active layer 220 may include a plurality of integrated devices. The plurality of integrated devices may include memory devices or logic devices. In some embodiments, the integrated devices, such as integrated circuits (IC) and large scale integrated circuits (LSI), may be formed in the active layer 220.

For example, the memory devices may include dynamic random-access memory (DRA M), static random-access memory (SRAM), flash memory, electrically erasable and programmable read-only memory (EEPROM), phase-change random-access memory (PRAM), magnetic random-access memory (RRAM) or resistive random-access memory (RRA M) devices.

For example, the logic devices include an AND, a NAND, an OR, a NOR, an exclusive OR (XOR), an exclusive NOR (XNOR), an inverter (INV), an adder (ADD), a buffer, a delay (DLY), a filter (FIL), a multiplexer (MXT/MXIT), an OR/AND/INVERTER (OAI), an AND/OR (AO), an AND/OR/INVERTER (AOI), a D flip-flop, a reset flip-flop, a master-slave flip-flop, a latch, a counter, or buffer devices. Additionally, the logic devices may include a central processing unit (CPU), a microprocessor unit (MPU), a graphics processing unit (GPU), or an application processor (AP).

In some embodiments, the active layer 220 may include a structure in which the upper active layer 222 is combined with the lower active layer 221. The bonding surface BS may include a surface where the upper active layer 222 is in contact with the lower active layer 221.

In some embodiments, the active layer 220 may include a cell on peri (CoP)-type integrated device. That is, the upper active layer 222 may include a cell area and the lower active layer 221 may include a peri area.

In some embodiments, the upper active layer 222 and the lower active layer 221 may be bonded to each other through hybrid bonding. Specifically, an upper conductive pad and an upper insulating layer may be located on the upper active layer 222 and a lower conductive pad and a lower insulating layer may be located on the lower active layer 221. The upper conductive pad and the lower conductive pad may be diffusion bonded so that the upper conductive pad and the lower conductive pad facing each other are expanded to be in contact with each other and become integrated with each other through diffusion of metal atoms. In the process of forming the upper conductive pad and the lower conductive pad, the upper insulating layer and the lower insulating layer may be diffusion bonded so that the upper insulating layer and the lower insulating layer facing each other are expanded to be in contact with each other and become integrated with each other through diffusion of metal atoms. However, the method of bonding the upper active layer 222 to the lower active layer 221 is not limited thereto.

In some embodiments, the bonding surface BS may have a bonding structure using an anisotropic conductive film (ACF) and a bonding structure using a connection member, such as a bump or a solder ball. In the bonding structure using the ACF, the ACF, which includes an ACF that conducts electricity in only one direction, may refer to a conductive film made in a film state by mixing fine conductive particles with an adhesive resin.

In some embodiments, the protective layer 230 may be spaced apart from the base substrate 210 with the active layer 220 in between. That is, the protective layer 230 may not be in direct contact with the base substrate 210. In some embodiments, a portion of the active layer 220 located within the scribe lane area SL among the active layers may be exposed to the outside because the protective layer 230 is not formed in a portion of the scribe lane area SL.

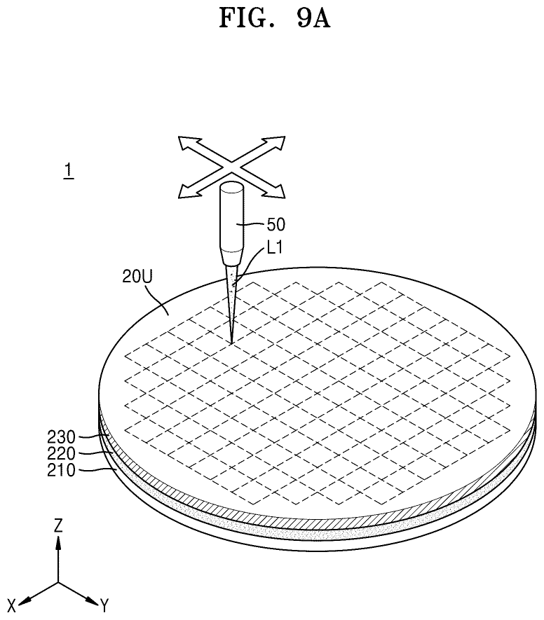

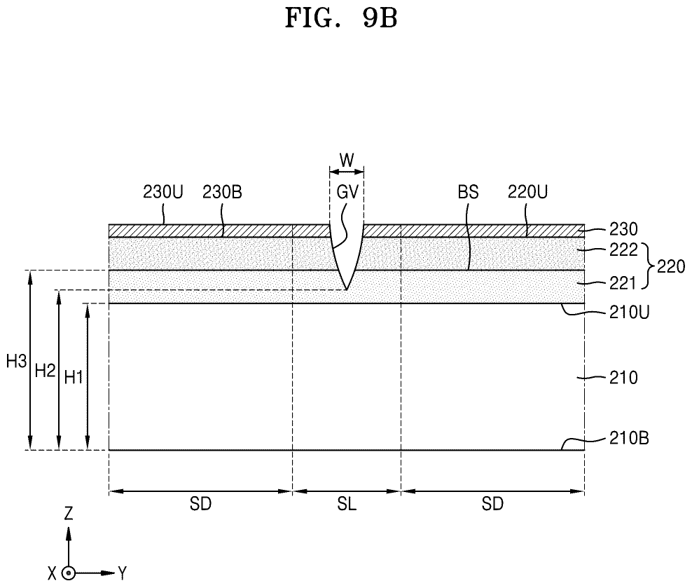

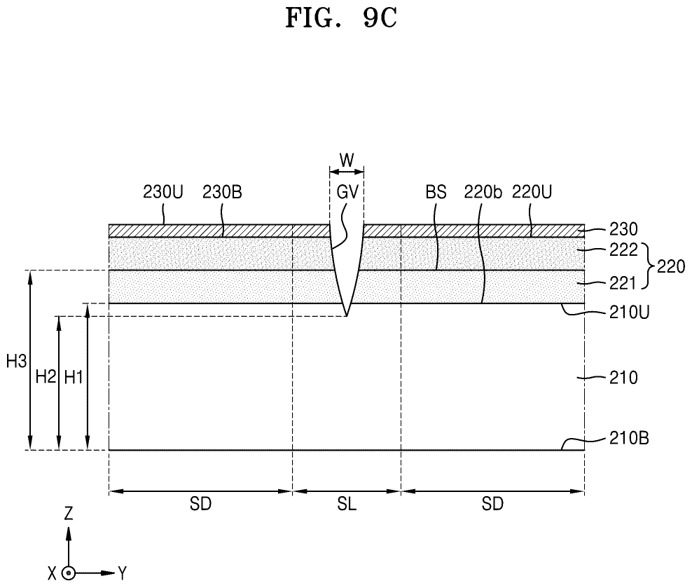

In some embodiments, the protective layer 230 may include a polymer chemical film. For example, the protective layer 230 may include photosensitive polyimide (PSPI) or polyimide (PI). For example, the protective layer 230 may include poly vinyl alcohol (PVA), polyethylene glycol (PEG), or polyethylene oxide (PEO). The protective layer 230 may prevent impurities generated in the process of forming the groove (GV in FIG. 9B) from reaching the active layer 220.

The wafer 20 may include a plurality of device formation areas SD in which a plurality of integrated devices are formed and a scribe lane area SL defining the plurality of device formation areas SD.

In some embodiments, the chuck table 40 may include an electrostatic chuck that fixes the wafer 20 using electrostatic force or a vacuum chuck that fixes the wafer 20 using vacuum. Alternatively, the wafer 20 may be fixed on the chuck table 40 through adhesive tape.

Referring to FIGS. 9A and 9B, the first laser beam L1 may be irradiated to the upper surface 20U of the wafer 20 to form a groove GV that removes at least a portion of each of the active layer 220 and the protective layer 230.

After positioning the first laser processing device 50 above the upper surface 20U of the wafer 20, the first laser processing device 50 may irradiate the first laser beam L1 onto the upper surface of the wafer 20, that is, the protective layer 230 and the active layer 220. While moving in the horizontal direction (X direction or Y direction), the first laser processing device 50 may completely remove the protective layer 230 in at least a portion of the scribe lane area SL and partially remove the active layer 220.

Accordingly, a portion of the bonding surface BS of the active layer 220 may be removed by the first laser beam L1. The groove GV may be formed in the space where the active layer 220 and the protective layer 230 are removed. A horizontal width W of the groove GV may decrease towards the base substrate 210. In an embodiment, the rate of change in the horizontal width W of the groove GV at the entrance area of the groove GV (e.g., the area adjacent to the upper surface of the wafer 20) may be less than the rate of change in the horizontal width W of the groove GV at the bottom area of the groove GV. As shown in FIGS. 9B and 9C, the bottom area of the groove GV may have a sharp shape. The bottom area of the groove GV may be V-shaped.

The first laser processing device 50 may include the laser processing device 1000 according to an embodiment of FIGS. 1A and 1B. The first laser beam L1 may include the laser beam L1 of FIGS. 1A and 1B. That is, the first laser processing device 50 may form a pattern of the first laser beam L1 based on the beam matrix BM. At this time, the beam matrix BM may include a beam pattern having a plurality of beam sizes.

In some embodiments, the bottom of the groove GV may be located within the lower active layer 220. For example, a vertical level H2 of the bottom of the groove GV may be lower than a vertical level H3 of the bonding surface BS and may be greater than a vertical level H1 of the upper surface 210U of the base substrate 210.

Referring to FIG. 9C, the first laser beam L1 may completely remove the protective layer 230 and the active layer 220 in at least a portion of the scribe lane area SL and remove a portion of the base substrate 210 to form the groove GV. The bottom of the groove GV may be located within the base substrate 210.

Referring again to FIG. 9B, the first laser beam L1 may have a wavelength that is absorbed by the protective layer 230 and the active layer 220. In some embodiments, the wavelength of the first laser beam L1 may be about 300 nm to about 800 nm. In some embodiments, the pulse width of the first laser beam L1 may be about 20 ns to about 80 ns. In some embodiments, the output of the first laser beam L1 may be about 1 W to about 5 W.

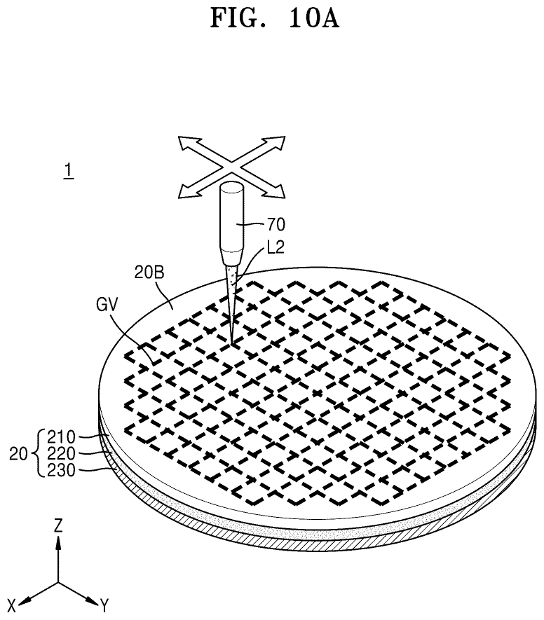

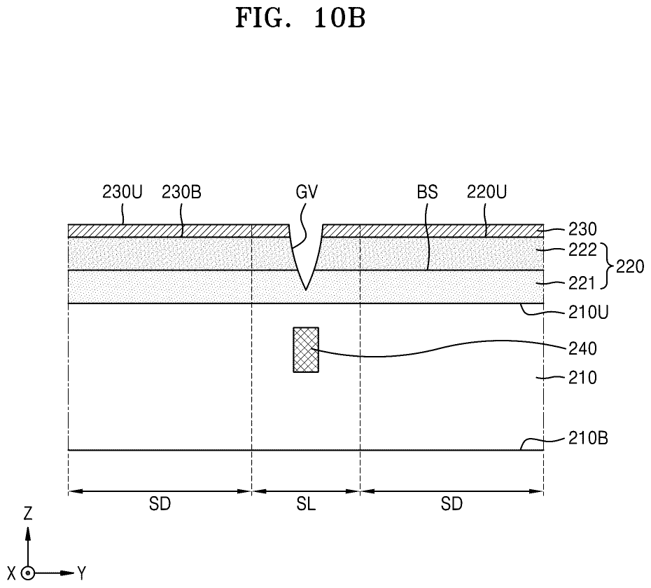

Referring to FIGS. 10A and 10B, a plurality of internal voids 240 may be formed inside the wafer 20 by irradiating the second laser beam L2 into the wafer 20.

The wafer 20 with the groove GV may be flipped and mounted on the chuck table 40 so that a bottom surface 20B of the wafer 20 faces upward. The wafer 20 is not limited to the above and may be mounted on the chuck table 40 so that the upper surface 20U of the wafer 20 faces upward.

The second laser processing device 70 that irradiates the second laser beam L2 may be aligned with the wafer 20 so that the condensing point of the second laser beam L2 and the groove GV are aligned in the vertical direction (Z direction). In some embodiments, the position of the groove GV may be measured using an imaging device (not shown) to align the wafer 20 with the second laser processing device 70. The second laser processing device 70 aligned with the wafer 20 may move in the horizontal direction (X direction or Y direction) along the groove GV.

Since the second laser beam L2 has a wavelength that is transparent to the base substrate 210, the condensing point may be located inside the base substrate 210. By condensing the second laser beam L2 along the groove GV through the second laser processing device 70, the plurality of internal voids 240 spaced apart from each other in a direction perpendicular to the groove GV may be formed inside the base substrate 210. As the plurality of internal voids 240 are formed inside the base substrate 210, cracks may be formed near the plurality of internal voids 240 in the base substrate 210.

In some embodiments, the wavelength of the second laser beam L2 may be about 800 nm to about 1200 nm. In some embodiments, the output of the second laser beam L2 may be about 1 W to about 3 W. In some embodiments, the pulse width of the second laser beam L2 may be about 20 ns to about 80 ns.

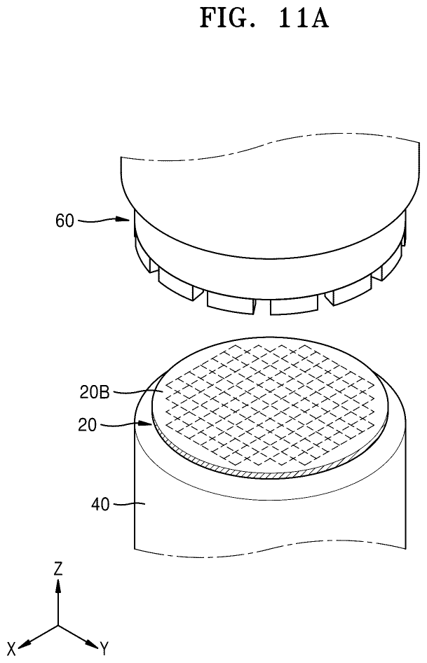

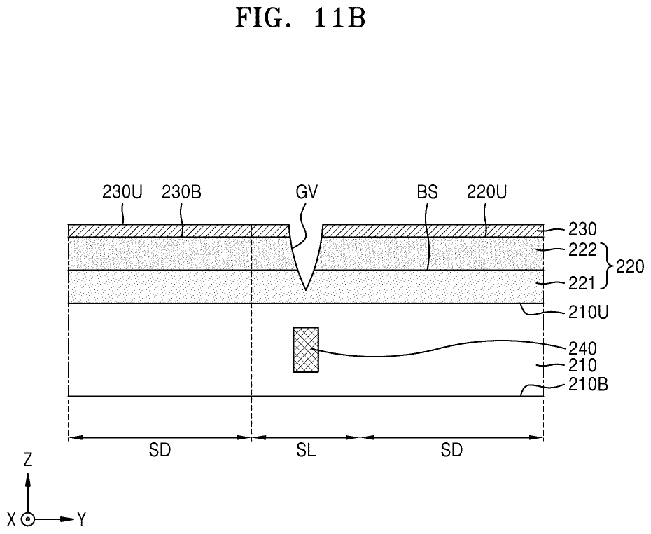

Referring to FIGS. 11A and 11B, the bottom surface 20B of the wafer 20 is ground to remove a lower portion of the base substrate 210. The grinding process is performed to form the base substrate 210 to a preset thickness.

The base substrate 210 may be formed to a preset thickness by positioning the grinding device 60 above the bottom surface 20B of the wafer 20, rotating the chuck table 40 supporting the wafer 20 and/or the grinding device 60, and grinding the bottom surface 20B of the wafer 20 in contact with the grinding device 60. For example, through the grinding process, a thickness of the base substrate 210 may be 100 μm.

In some embodiments, a portion of the plurality of internal voids 240 may be removed through the grinding process. In some embodiments, the grinding process may include a chemical mechanical polishing (CMP) process.

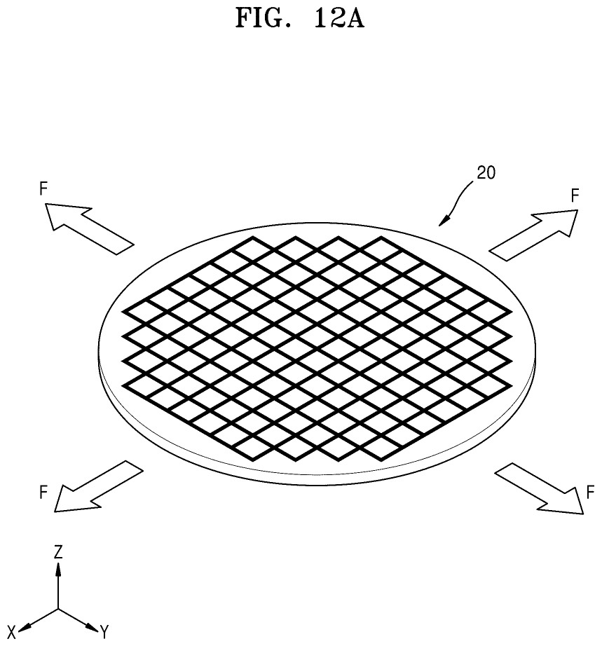

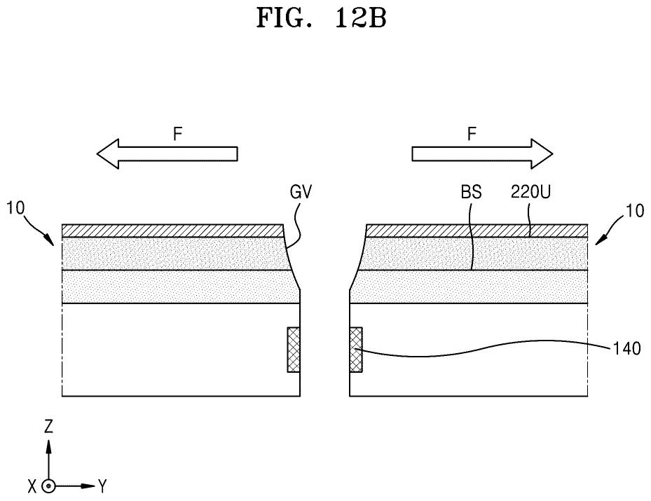

Referring to FIGS. 12A and 12B with FIG. 11B, the wafer 20 may be divided along the plurality of internal voids 240 to form a plurality of semiconductor chips.

By applying an external force to the wafer 20, the cracks may be formed from the plurality of internal voids 240 of the base substrate 210 toward the groove GV, thereby fracturing the wafer 20 along the plurality of internal voids 240. In some embodiments, the external force may be applied to the wafer 20 while attaching the wafer 20 to dicing tape (not shown) and expanding the dicing tape.

The plurality of internal voids 240 of the wafer 20 may be more easily damaged by the external force than other areas. As the dicing tape expands, cracks may start from the plurality of internal voids 240 due to the external force applied to the wafer 20. The cracks extend upward and downward from the plurality of internal voids 240 and may contact the lower surface 210B of the base substrate 210 and the groove GV. Accordingly, the wafer 20 may be fractured and divided into a plurality of semiconductor chips 10.

The wafer dicing method (S10) according to an embodiment may form the groove GV in the wafer 20 by using the laser processing device 1000 that irradiates a laser beam of a pattern formed based on the beam matrix BM having a plurality of beam sizes. As described above, because the beam matrix BM includes a beam pattern having a plurality of beam sizes, the shape of the groove GV may have a deep depth in the vertical direction while having a horizontal width to prevent the formation of the re-melting void. For example, the groove GV may prevent the formation of the re-melting void by expanding the width of the entrance area, that is, the area adjacent to the upper surface 20U of the wafer 20 where the groove GV is formed.

As the groove GV extends from the upper surface 220U of the active layer 220 to the bottom of the bonding surface BS of the active layer 220 in the vertical direction (Z direction), cracks starting from the plurality of internal voids 240 may not extend to the bonding surface BS of the active layer 220. That is, cracks generated from the plurality of internal voids 240 toward the groove GV may contact the groove GV under the bonding surface BS of the active layer 220. Accordingly, damage to the vicinity of the bonding surface BS of the active layer 220 may be suppressed in the process of dividing the wafer 20.

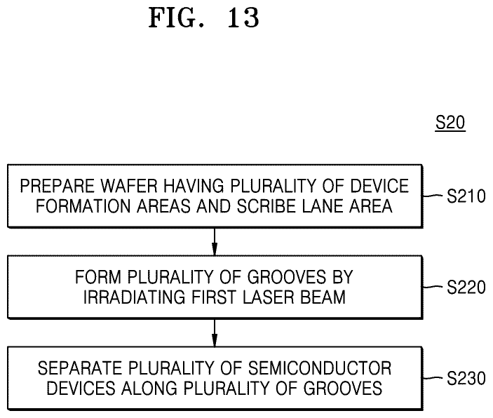

FIG. 13 is a schematic flowchart of a wafer dicing method (S20) according to an embodiment.

Referring to FIG. 13, the wafer dicing method (S20) according to an embodiment may include preparing a wafer having a plurality of device formation areas and a scribe lane area (S210), forming a plurality of grooves by irradiating a first laser beam (S220), and separating a plurality of semiconductor devices along the plurality of grooves (S230).

The operation S210 of preparing the wafer having the plurality of device formation areas and the scribe lane area of FIG. 13 may correspond to the operation S110 described above with reference to FIG. 7. The operation S220 of forming the grooves by irradiating the first laser beam of FIG. 13 may correspond to operation S120 described above with reference to FIG. 7. Referring to FIG. 13, in the wafer dicing method (S20) according to an embodiment, the operation S130 of forming the plurality of internal voids by irradiating the second laser beam may be omitted due to the grooves formed by irradiating the first laser beam, which is different from FIG. 7. In other words, the plurality of semiconductor devices may be separated by using only the plurality of grooves.

While the inventive concept has been particularly shown and described with reference to embodiments thereof, it will be understood that various changes in form and details may be made therein without departing from the scope of the following claims.

What is claimed is:

1. A laser processing device comprising:
a beam generator configured to generate a laser beam; and
a beam shaper configured to split the laser beam generated by the beam generator into a plurality of laser beams through diffraction, and to form at least one beam pattern of the plurality of laser beams via a beam matrix, wherein the at least one beam pattern comprises a plurality of beam sizes.

2. The laser processing device of claim 1, wherein the at least one beam pattern comprises first beam patterns having a first beam size, and second beam patterns having a second beam size that is different from the first beam size, wherein the first beam patterns are arranged in a first direction within the beam matrix.

3. The laser processing device of claim 2, wherein the second beam patterns are arranged in a second direction perpendicular to the first direction within the beam matrix.

4. The laser processing device of claim 3, wherein the second beam size of the second beam patterns is more than twice the first beam size of the first beam patterns.

5. The laser processing device of claim 4, wherein the first beam patterns are located at one end in the first direction within the beam matrix.

6. The laser processing device of claim 3, wherein a distance between adjacent ones of the second beam patterns in the second direction is less than the second beam size of the second beam patterns.

7. The laser processing device of claim 3, wherein a distance between one of the first beam patterns and one of the second beam patterns that are adjacent to each other is greater than the first beam size of the first beam patterns within the beam matrix.

8. The laser processing device of claim 3, wherein one of the first beam patterns is adjacent to the second beam patterns along the first direction.

9. The laser processing device of claim 1, wherein the at least one beam pattern comprises a first beam pattern having a first beam size, a second beam pattern having a second beam size that is different from the first beam size, and a third beam pattern having a third beam size that is different from the first beam size and the second beam size, wherein the first beam pattern, the second beam pattern, and the third beam pattern are sequentially arranged along the first direction within the beam matrix.

10. A wafer dicing method comprising:
preparing a wafer having a plurality of device formation areas where a plurality of semiconductor devices are located and a scribe lane area defining the plurality of device formation areas; and
forming a groove that at least partially penetrates the wafer in the scribe lane area, wherein the forming of the groove comprises irradiating a first laser beam onto an upper surface of the wafer, wherein the first laser beam is split into at least one pattern of a plurality of laser beams via a beam matrix, wherein the at least one pattern has a plurality of beam sizes.

11. The wafer dicing method of claim 10, wherein the at least one beam pattern comprises first beam patterns having a first beam size and second beam patterns having a second beam size that is at least twice the first beam size.

12. The wafer dicing method of claim 11, wherein a distance between adjacent ones of the second beam patterns is less than the second beam size of the second beam patterns.

13. The wafer dicing method of claim 11, wherein the first beam patterns are arranged in a first direction and the second beam patterns are arranged in a second direction that is perpendicular to the first direction.

14. The wafer dicing method of claim 13, wherein the first direction is parallel to an extension direction of the groove.

15. The wafer dicing method of claim 14, wherein one of the first beam patterns is located at one end in the first direction within the beam matrix.

16. The wafer dicing method of claim 10, wherein the at least one pattern is parallel to an extension direction of the groove.

17. The wafer dicing method of claim 10, further comprising:
irradiating a second laser beam along a lower surface of the wafer to form a plurality of internal voids in the wafer; and
separating the plurality of semiconductor devices along the plurality of internal voids.

18. The wafer dicing method of claim 10, further comprising separating the plurality of semiconductor devices along the groove.

19. A wafer dicing method comprising:
preparing a wafer having a plurality of device formation areas where a plurality of semiconductor devices are located and a scribe lane area defining the plurality of device formation areas;
generating a laser beam;
splitting the laser beam into a plurality of laser beams arranged in at least one pattern via a beam matrix; and
irradiating the wafer with the plurality of laser beams arranged in the at least one pattern, wherein the at least one pattern comprises first beam patterns and second beam patterns having a diameter at least twice a diameter of the first beam patterns, and
wherein a distance between adjacent ones of the second beam patterns is less than a diameter of each of the second beam patterns.

20. The wafer dicing method of claim 19, wherein the irradiating the wafer comprises forming a groove that at least partially penetrates the wafer, wherein the first beam patterns are arranged in a direction parallel to an extension direction of the groove.
